(19) United States
(12) Patent Application Publication
(10) Pub. No.: US 2026/0082840 A1
(43) Pub. Date: Mar. 19, 2026

(54) METHOD FOR MANUFACTURING SEMICONDUCTOR DEVICE, AND SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Seiya SAKAKURA, Hakusan Ishikawa (JP); Shinji ONZUKA, Nonoichi Ishikawa (JP)

(21) Appl. No.: 19/069,102

(22) Filed: Mar. 3, 2025

(30) Foreign Application Priority Data
Sep. 18, 2024 (JP) 2024-161304

(51) Int. Cl. H01L 21/304; H01L 21/3205; H01L 21/78; H10D 62/10

(52) U.S. Cl. CPC H10P 52/00; H10D 62/117; H10P 14/412; H10P 54/00

(57) ABSTRACT

A method for manufacturing a semiconductor device has a groove portion forming step, a first attachment step, a grinding step, a first ashing step, and a metal film forming step. The groove portion forming step is a step of forming a plurality of groove portions in a base material from a device surface side in which an element region is formed. The grinding step is a step of grinding the base material from a side opposite to the device surface to form a back surface. The grinding step is a step of singulating the base material by making a thickness of the base material equal to or less than depths of the groove portions. The metal film forming step is a step of forming a metal film on the back surface.

### CROSS-REFERENCE TO RELATED APPLICATION

This application is based upon and claims the benefit of priority from Japanese Patent Application No. 2024-161304, filed on Sep. 18, 2024, the entire contents of which are incorporated herein by reference.

### FIELD

Embodiments described herein relate generally to a method for manufacturing a semiconductor device, and a semiconductor device.

### BACKGROUND

In the process of manufacturing semiconductor devices, a singulation step of singulating a base material (wafer) into semiconductor chips is carried out. A singulation step is a step that is likely to cause burrs and chippings in semiconductor devices, and may reduce the manufacturing yield of the semiconductor devices.

### BRIEF DESCRIPTION OF THE DRAWINGS

FIG. 1 is a schematic diagram of a semiconductor device of a first embodiment.

FIG. 2 is a schematic cross-sectional view of the semiconductor device of the first embodiment along line II-II in FIG. 1.

FIG. 3 is a flowchart showing a method for manufacturing the semiconductor device of the first embodiment.

FIG. 4 is a schematic diagram showing a device surface forming step of the first embodiment.

FIG. 5 is a schematic diagram showing a first step of a groove portion forming step of the first embodiment.

FIG. 6 is a schematic diagram showing a second step of the groove portion forming step of the first embodiment.

FIG. 7 is a schematic diagram showing a first attachment step of the first embodiment.

FIG. 8 is a schematic diagram showing a grinding step of the first embodiment.

FIG. 9 is a schematic diagram showing a first ashing step of the first embodiment.

FIG. 10 is a schematic diagram showing a protective film forming step of the first embodiment.

FIG. 11 is a schematic diagram showing an etching step of the first embodiment.

FIG. 12 is a schematic diagram showing a metal film forming step of the first embodiment.

FIG. 13 is a schematic diagram showing a second ashing step of the first embodiment.

FIG. 14 is a schematic diagram showing a second attachment step of the first embodiment.

FIG. 15 is a schematic diagram showing a support substrate detachment step of the first embodiment.

FIG. 16 is a schematic cross-sectional view of a semiconductor device of a second embodiment.

FIG. 17 is a schematic diagram showing a groove portion forming step of the second embodiment.

FIG. 18 is a schematic diagram showing a grinding step of the second embodiment.

FIG. 19 is a schematic diagram showing a base material after a first ashing step and a metal film forming step of the second embodiment have been performed.

FIG. 20 is a schematic diagram of a base material after a groove portion forming step of the present modified example has been performed.

FIG. 21 is a schematic diagram showing a grinding step of the present modified example.

FIG. 22 is a schematic diagram showing a base material after a first ashing step and a metal film forming step of the present modified example have been performed.

### DETAILED DESCRIPTION

A method for manufacturing a semiconductor device of an embodiment includes a groove portion forming step, a first attachment step, a grinding step, a first ashing step, and a metal film forming step. The groove portion forming step is a step of forming a plurality of groove portions in a base material from a device surface side on which an element region is formed. The first attachment step is a step of attaching the device surface to a support substrate via an adhesive. The grinding step is a step of grinding the base material from a side opposite to the device surface to form a back surface. The grinding step is a step of making a thickness of the base material equal to or less than depths of the groove portions, thereby singulating the base material. The first ashing step is a step of ashing the adhesive inside the groove portions from the back surface side. The metal film forming step is a step of forming a metal film on the back surface. A method for manufacturing a semiconductor device and a semiconductor device of embodiments will be described below with reference to the drawings.

In the present specification, in order to show positional relationships between components and the like, an upward direction of the figures will be described as “up” and a downward direction of the figures as “down.” In the present specification, the concepts of “up” and “down” do not necessarily have to be terms indicating relationships with respect to the direction of gravity.

### First Embodiment

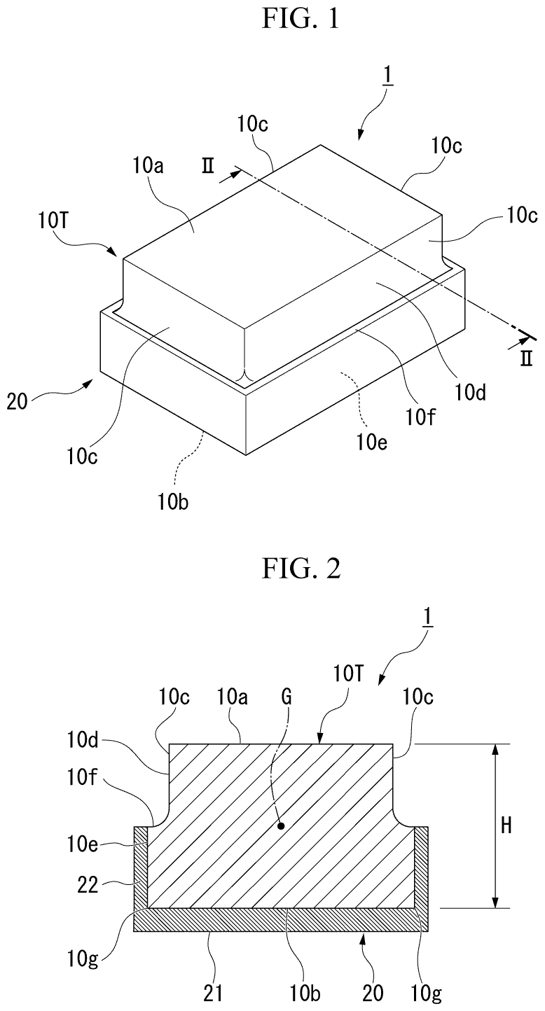

FIG. 1 is a schematic diagram of a semiconductor device 1 of a first embodiment. FIG. 2 is a schematic cross-sectional view of the semiconductor device 1 of the first embodiment along line II-II in FIG. 1.

The semiconductor device 1 of the present embodiment is, for example, a metal-oxide-semiconductor field-effect transistor (MOSFET), an insulated gate bipolar transistor (IGBT), or the like. The semiconductor device 1 of the present embodiment includes a rectangular plate-shaped semiconductor chip 10T and a metal film 20 provided on a surface of the semiconductor chip 10T.

The semiconductor chip 10T is made of a semiconductor material. In the present specification, the semiconductor material is, for example, silicon (Si), silicon carbide (SiC), gallium arsenide (GaAs), or gallium nitride (GaN), but is not limited to these.

As shown in FIGS. 1 and 2, the semiconductor chip 10T has a device surface (first surface) 10a, a back surface (second surface) 10b located on a side opposite to the device surface 10a, and four side surfaces 10c connecting the device surface 10a to the back surface 10b. Also, the number of side surfaces 10c is not limited to the present embodiment. For example, if the device surface 10a and the back surface 10b are hexagonal in a plan view, the semiconductor chip 10T has six side surfaces 10c.

An element region is formed on the device surface 10a. That is, a MOSFET device or an IGBT device is formed on the device surface 10a, for example. In the following description, as shown in FIG. 2, a distance dimension between the device surface 10a and the back surface 10b will be referred to as a thickness H of the semiconductor chip 10T.

As shown in FIG. 2, the side surface 10c of the semiconductor chip 10T has a step shape. The side surface 10c has a first side surface portion 10d, a second side surface portion 10e, and a step surface portion 10f.

In the present embodiment, the first side surface portion 10d and the second side surface portion 10e both extend along a plane perpendicular to the device surface 10a. Accordingly, the first side surface portion 10d and the second side surface portion 10e of the present embodiment are parallel to each other. Also, the first side surface portion 10d and the second side surface portion 10e may be inclined with respect to a direction perpendicular to the device surface 10a. The first side surface portion 10d is connected to the device surface 10a. The second side surface portion 10e is located closer to the back surface 10b than the first side surface portion 10d in a normal direction of the device surface 10a. The second side surface portion 10e is connected to the back surface 10b. In addition, the second side surface portion 10e is located at a position farther from a center of gravity G of the semiconductor chip 10T than the first side surface portion 10d in a normal direction of the first side surface portion 10d. That is, when the normal direction of the device surface 10a is a vertical direction, the second side surface portion 10e is located outward from the first side surface portion 10d in a horizontal direction.

The step surface portion 10f extends substantially parallel to the device surface 10a and the back surface 10b. The step surface portion 10f faces substantially the same direction as the device surface 10a. The step surface portion 10f connects the first side surface portion 10d to the second side surface portion 10e. As described above, the step surface portion 10f of the present embodiment is parallel to the device surface 10a, but the step surface portion 10f may be inclined with respect to the device surface 10a.

The metal film 20 is provided on a part of the surface of the semiconductor chip 10T. A metal included in the metal film 20 is, for example, copper (Cu), aluminum (Al), nickel (Ni), titanium (Ti), silver (Ag), gold (Au), or the like, but is not limited to these.

The metal film 20 may be configured of a plurality of layers made of different metal materials. Examples of a layer structure used for the metal film 20 include one having a first layer made of titanium (Ti) formed on the surface of the semiconductor chip 10T and a second layer made of nickel (Ni) formed on a surface of the first layer.

The metal film 20 of the present embodiment has a back surface covering portion (second surface covering portion) 21 and a side surface covering portion 22. In the present embodiment, the back surface covering portion 21 and the side surface covering portion 22 are connected to each other.

The back surface covering portion 21 covers the entire back surface 10b of the semiconductor chip 10T. For example, if the semiconductor chip 10T is a MOSFET chip, the back surface covering portion 21 functions as a drain electrode of the MOSFET.

The side surface covering portion 22 covers at least a part of the side surface 10c of the semiconductor chip 10T. The side surface covering portion 22 is provided in a certain region from a corner portion 10g between the side surface 10c and the back surface 10b toward the device surface 10a. The side surface covering portion 22 of the present embodiment covers the entire second side surface portion 10e. According to the present embodiment, the metal film 20 covers at least a part of the side surface 10c, and thus the part of the side surface 10c can be protected by the metal film 20.

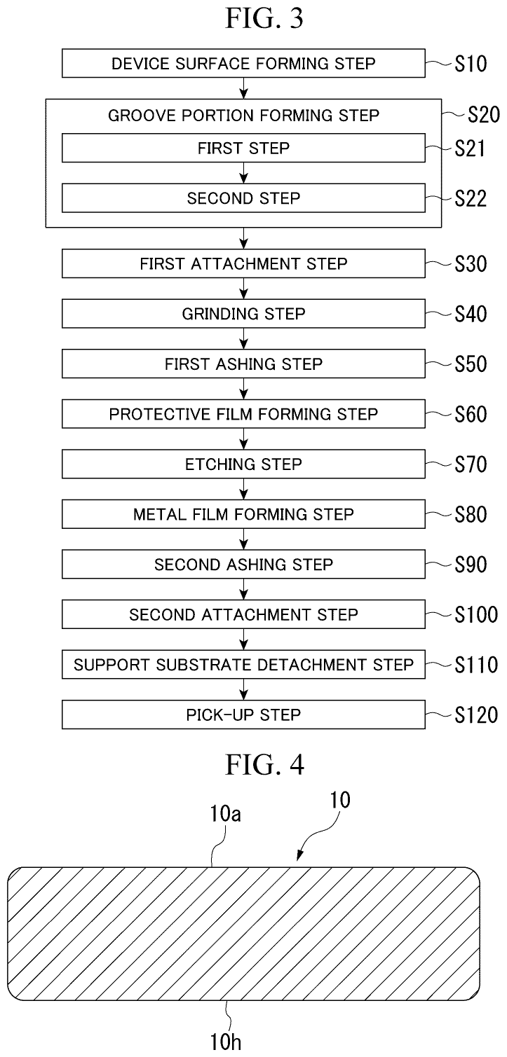

FIG. 3 is a flowchart showing a method for manufacturing the semiconductor device 1 of the present embodiment. The method for manufacturing the semiconductor device 1 of the present embodiment has a device surface forming step S10, a groove portion forming step S20, a first attachment step (attachment step) S30, a grinding step S40, a first ashing step (ashing step) S50, a protective film forming step S60, an etching step S70, a metal film forming step (film forming step) S80, a second ashing step S90, a second attachment step S100, a support substrate detachment step S110, and a pick-up step S120. In addition, in the present embodiment, the groove portion forming step S20 includes a first step S21 and a second step S22.

FIG. 4 is a schematic diagram showing the device surface forming step S10 of the present embodiment. The device surface forming step S10 is a step in which an element region is formed on one surface of a disk-shaped base material 10 made of a semiconductor material, and this surface is used as the device surface 10a. The element region is, for example, an element pattern of MOSFET or IGBT devices, or a circuit pattern of analog circuits, integrated circuits, or the like. In addition, in the following description, a surface on a side opposite to the device surface 10a before the grinding step S40, which will be described later, will be referred to as an initial back surface 10h. Although not shown in the figure, the device surface forming step S10 and the subsequent groove portion forming step S20 are performed with the base material 10 supported on the initial back surface 10h.

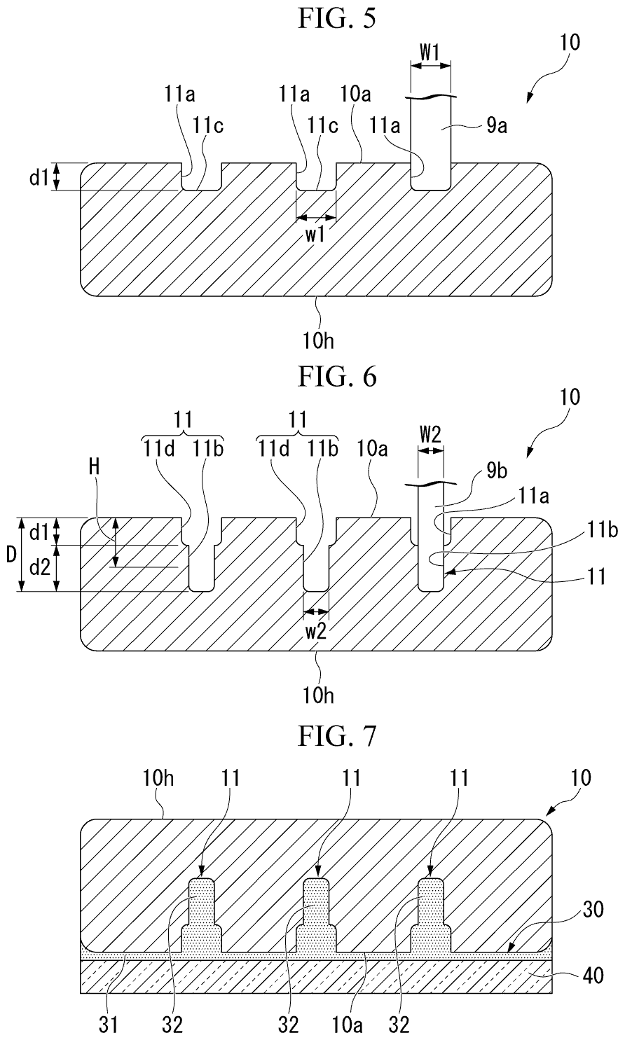

FIG. 5 is a schematic diagram showing the first step S21 of the groove portion forming step S20 of the present embodiment. FIG. 6 is a schematic diagram showing the second step S22 of the groove portion forming step S20 of the present embodiment. The groove portion forming step S20 of the present embodiment is a step of forming a plurality of groove portions 11 on the device surface 10a.

In the groove portion forming step S20 of the present embodiment, the base material 10 is machined using a first dicing blade 9a and a second dicing blade 9b to form the plurality of groove portions 11. The plurality of groove portions 11 are formed in the disk-shaped base material 10 in directions orthogonal to each other. Thus, the device surface 10a of the base material 10 is divided into a plurality of rectangular areas. In addition, in the groove portion forming step S20 of the present embodiment, after first grooves 11a are formed, second grooves 11b are formed at bottom portions 11c of the first grooves 11a. That is, the groove portions 11 formed in the groove portion forming step S20 include the first grooves 11a and the second grooves 11b formed on the same straight line.

The first step S21 shown in FIG. 5 is a step of forming the first grooves 11a on the device surface 10a. The first step S21 is performed using the first dicing blade 9a having a first blade width W1. The first grooves 11a each have a first groove width w1 that is substantially equal to the first blade width W1.

The second step S22 shown in FIG. 6 is a step of forming the second grooves 11b in centers of the bottom portions 11c of the first grooves 11a in a width direction thereof. The second step S22 is performed using the second dicing blade 9b having a second blade width W2. The second grooves 11b each have a second groove width w2 that is substantially equal to the second blade width W2. The second blade width W2 is smaller than the first blade width W1. Accordingly, the second groove width w2 is smaller than the first groove width w1. The second grooves 11b are machined by aligning a center of the second dicing blade 9b in a blade width direction thereof with the centers of the bottom portions 11c of the first grooves 11a in the width direction.

A depth D of the groove portion 11 is the sum (d1+d2) of a depth d1 of the first groove 11a and a depth d2 of the second groove 11b. A thickness H of the semiconductor chip 10T (see FIG. 2) manufactured by the manufacturing method of the present embodiment is smaller than the depth D of the groove portion 11 and larger than the depth d1 of the first groove 11a.

FIG. 7 is a schematic diagram showing the first attachment step S30 of the present embodiment. In the process of moving from the groove portion forming step S20 to the first attachment step S30, the base material 10 is turned upside down. The first attachment step S30 is a step of attaching the device surface 10a facing downward to a support substrate 40 via an adhesive 30. Through the first attachment step S30, the base material 10 is fixed to the support substrate 40.

In the first attachment step S30, first, the device surface 10a is coated with the uncured adhesive 30. Thus, the uncured adhesive 30 infiltrates the inside of the groove portions 11 formed in the device surface 10a. Next, the device surface 10a and a support surface of the support substrate 40 are attached to each other. Further, the adhesive 30 hardens, completing the first attachment step S30.

For the adhesive 30, for example, an acrylic adhesive, an epoxy adhesive, or a silicon adhesive can be preferably used. Also, the support substrate 40 is a plate-shaped member made of glass, for example. In the following description, a portion of the cured adhesive 30 disposed between the device surface 10a and the support substrate 40 will be called an adhesive layer 31, and a portion thereof disposed inside the groove portions 11 will be called an in-groove adhesive 32.

Also, FIG. 7 illustrates a case in which the adhesive 30 is completely filled inside the groove portions 11, but a filling state of the adhesive 30 is not limited to the state shown in FIG. 7. For example, the adhesive 30 may be filled halfway into the groove portions 11 while gaps are provided near the bottom portions of the groove portions 11.

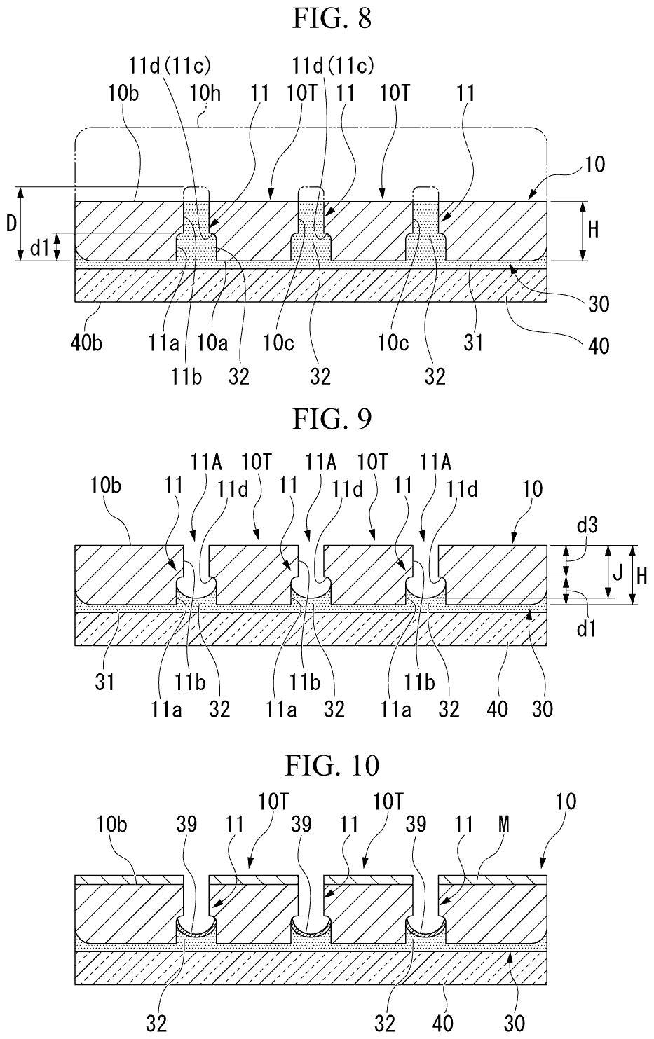

FIG. 8 is a schematic diagram showing the grinding step S40 of the present embodiment. The grinding step S40 is a step of grinding the initial back surface 10h of the base material 10 to form the back surface (second surface) 10b. The grinding step S40 of the present embodiment is performed while the base material 10 is supported by the support substrate 40. Also, although not shown in the figure, the grinding step S40 is performed while a protective tape is attached to the substrate back surface 40b of the support substrate 40. The protective tape protects the substrate back surface 40b from chippings generated in the grinding step S40. The protective tape is attached to the substrate back surface 40b before the grinding step S40 and is removed after the grinding step S40.

In the grinding step S40, the base material 10 is ground to have a thickness H. The thickness H is smaller than the depth D of the groove portions 11. For this reason, through the grinding step S40, the groove portions 11 formed on the device surface 10a penetrate to the back surface 10b. Thus, the base material 10 is singulated to form semiconductor chips 10T. Also, the thickness H is larger than the depth d1 of the first grooves 11a. For this reason, step portions 11d resulting from the bottom portions 11c of the first grooves 11a are formed on the side surfaces 10c of the singulated semiconductor chip 10T.

As described above, the groove portions 11 of the present embodiment are filled with the adhesive 30. For this reason, in the grinding step S40, the groove portions 11 penetrate the base material 10, and the in-groove adhesive 32 is exposed from the back surface 10b. That is, the grinding step S40 is a step of exposing the in-groove adhesive 32 from the back surface 10b side.

FIG. 9 is a schematic diagram showing the first ashing step S50 of the present embodiment. The first ashing step S50 is a step of performing an ashing step on the adhesive 30 (for example, the in-groove adhesive 32) inside the groove portions 11 from the back surface 10b side. Before the first ashing step S50, the back surface 10b is a uniform flat surface because the groove portions 11 are filled with the in-groove adhesive 32. Through the first ashing step S50, the in-groove adhesive 32 is ashed away from the back surface 10b, forming concave grooves 11A. Inner side surfaces of the concave grooves 11A are formed by side surfaces of the semiconductor chips 10T and the in-groove adhesive 32. That is, bottom portions of the concave grooves 11A are formed by the in-groove adhesive 32.

In the present embodiment, the first ashing step S50 is, for example, a step of performing plasma ashing. Also, other ashing methods may be adopted for the first ashing step S50.

In the first ashing step S50, by adjusting processing conditions such as a processing time, output of a high frequency wave for exciting plasma, and an oxygen partial pressure, an amount of ashing the adhesive 30 can be adjusted. That is, in the first ashing step S50, a depth J of the in-groove adhesive 32 to be removed can be adjusted.

If the adhesive 30 is removed in the first ashing step S50 by the thickness H of the semiconductor chip 10T or more, not only the in-groove adhesive 32 but also a part of the adhesive layer 31 is removed. In this case, fixation of the semiconductor chip 10T to the support substrate 40 by the adhesive layer 31 may become unstable. Accordingly, the depth J of the in-groove adhesive 32 to be removed in the first ashing step S50 is preferably equal to or less than the thickness H of the semiconductor chip 10T.

As shown in FIG. 9, a difference (H−d1) between the thickness H of the semiconductor chip 10T and the depth d1 of the first groove 11a is defined as a step distance d3. The step distance d3 is a distance dimension between the back surface 10b and the step portions 11d in the thickness direction of the semiconductor chip 10T. The depth J of the in-groove adhesive 32 removed in the first ashing step S50 is greater than the step distance d3. For this reason, in the first ashing step S50, the step portions 11d can be exposed from the in-groove adhesive 32. According to the first ashing step S50 of the present embodiment, a step shape appears on the inner side surface of the concave groove 11A, the groove width of which increases from the back surface 10b toward the device surface 10a. This step shape is formed in the groove portion forming step S20.

FIG. 10 is a schematic diagram showing the protective film forming step S60 of the present embodiment. The protective film forming step S60 is performed for the purpose of protecting the adhesive 30 in the subsequent etching step S70. Accordingly, if the etching step S70 is omitted, the protective film forming step S60 can also be omitted. Further, even when the etching step S70 is performed, if there is no risk of damage to the adhesive 30 in the etching step S70, the protective film forming step S60 can be omitted.

In the protective film forming step S60, a protective film 39 is formed on a surface of the in-groove adhesive 32. In the protective film forming step S60 of the present embodiment, for example, by ion implantation, diamond-like carbon is formed as the protective film 39 on the surface of the in-groove adhesive 32. In addition, in the protective film forming step S60, ions are implanted into the back surface 10b of the base material 10, and an ion-implanted layer M is formed in the base material 10. The ion-implanted layer M is removed in the next step, the etching step S70.

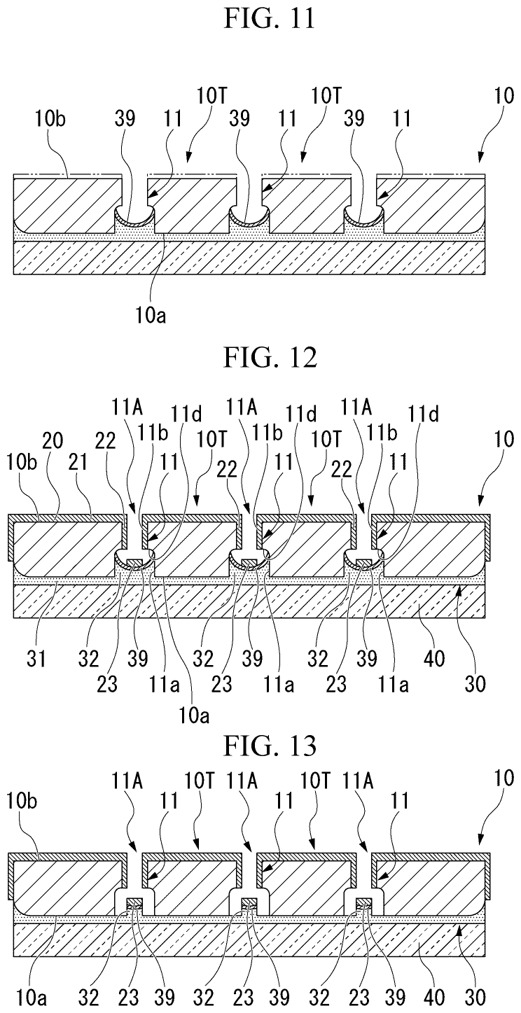

FIG. 11 is a schematic diagram showing the etching step S70 of the present embodiment. In the etching step S70, the back surface 10b of the semiconductor chip 10T is etched to adjust a surface roughness of the back surface 10b. The etching step S70 in the present embodiment is, for example, a step of providing a mirror finish to the back surface 10b. Also, the etching step S70 is, for example, a step of performing wet etching on the back surface 10b. In the etching step S70, the in-groove adhesive 32 is protected from a chemical solution by the protective film 39.

Further, if surface properties of the back surface 10b required for the semiconductor chip 10T can be sufficiently achieved by the grinded surface, the etching step S70 and the protective film forming step S60 performed in conjunction with the etching step S70 may be omitted. Also, the etching step S70 may be performed before the first ashing step S50.

FIG. 12 is a schematic diagram showing the metal film forming step S80 of the present embodiment. The metal film forming step S80 is a step of forming the metal film 20 on the back surface 10b of the base material 10. The metal film forming step S80 of the present embodiment is performed while the base material 10 is supported by the support substrate 40.

Also, before the metal film forming step S80, impurities may be diffused from the back surface 10b side into the base material 10. In this case, it is preferable to dope impurities from the back surface 10b side by ion implantation and then perform laser annealing on the back surface 10b.

The metal film forming step S80 of the present embodiment is a step of forming the metal film 20 on the back surface 10b of the semiconductor chip 10T by chemical vapor deposition (CVD) or physical vapor deposition (PVD), or the like. In the metal film forming step S80, the metal film 20 may be formed of a plurality of layers. As described above, the concave groove 11A opens on the back surface 10b of the base material 10. For this reason, a part of the metal film 20 is also formed on a part of the inner side surface of the concave groove 11A. The metal film 20 includes the back surface covering portion 21 formed on the back surface 10b, the side surface covering portion 22 formed on the inner surface of the concave groove 11A, and an adhesive covering portion 23 formed on the bottom portion of the concave groove 11A and on the surface of the protective film 39.

The concave groove 11A is provided on the back surface 10b side of the base material 10. In the metal film forming step S80, some of metal particles penetrate into the concave groove 11A. An amount of metal particles deposited on the inner surface of the concave groove 11A is likely to be larger in a region close to the back surface 10b. For this reason, the side surface covering portion 22 is likely to be thicker in the region close to the back surface 10b.

In addition, the step portions 11d are provided on the inner surfaces of the concave grooves 11A. According to the present embodiment, since the step portions 11d of the concave grooves 11A function as shields, the metal particles are unlikely to deposit directly below the step portions 11d. That is, the side surface covering portion 22 is unlikely to be formed directly below the step portions 11d. Also, although some of the metal particles are deposited on the surface of the protective film 39 directly below an opening of the concave groove 11A, they are unlikely to be deposited in portions that overlap the step portions 11d when viewed in a vertical direction. For this reason, the adhesive covering portion 23 is formed only at a center of the in-groove adhesive 32 in a width direction thereof and is unlikely to be connected to the side surface covering portion 22.

FIG. 13 is a schematic diagram showing the second ashing step S90 of the present embodiment. The second ashing step S90 is a step of removing a portion of the protective film 39 and the in-groove adhesive 32 located between the semiconductor chips 10T. For example, similarly to the first ashing step S50, the second ashing step S90 may be performed by a plasma ashing method, or may be performed by another ashing method. Also, if the adhesive 30 can be completely removed from the semiconductor chip 10T in the support substrate detachment step S110, which will be described later, the second ashing step S90 may be omitted.

Also, FIG. 13 illustrates a state in which parts of the adhesive covering portion 23, the protective film 39, and the in-groove adhesive 32 remain inside the concave groove 11A after the second ashing step S90. However, in the second ashing step S90, the in-groove adhesive 32 may be completely ashed, and the adhesive covering portion 23, the protective film 39, and the in-groove adhesive 32 may be completely removed from the inside of the concave groove 11A.

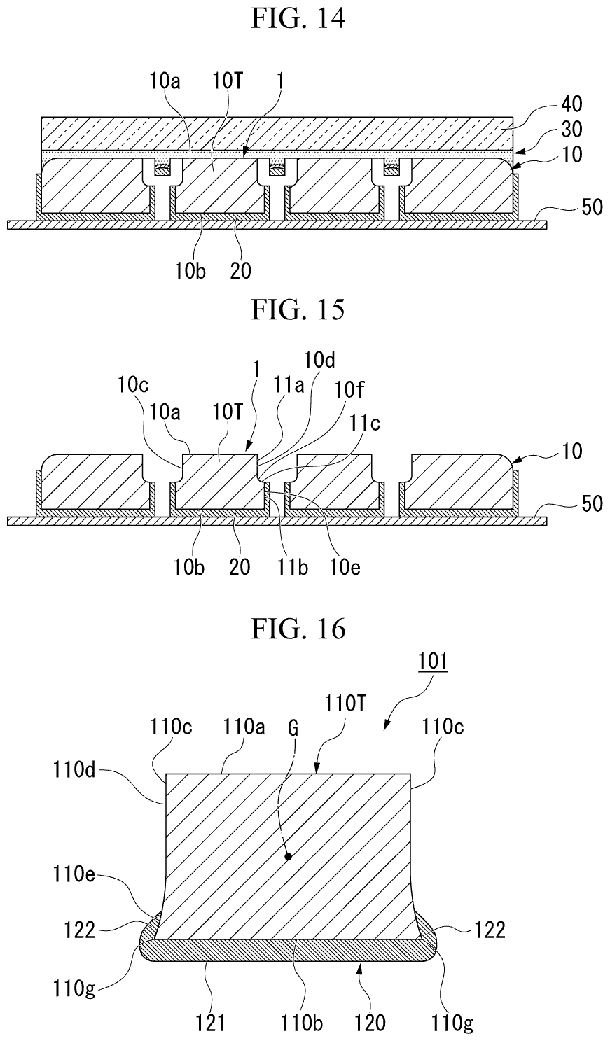

FIG. 14 is a schematic diagram showing the second attachment step S100 of the present embodiment. In the process of moving from the second ashing step S90 to the second attachment step S100, the base material 10 is turned upside down. The second attachment step S100 is a step of attaching the base material 10 to a dicing tape 50 on a side opposite to the support substrate 40. In the present embodiment, since the metal film 20 is provided on the back surface 10b side of the base material 10, the base material 10 is attached to the dicing tape 50 via the metal film 20.

FIG. 15 is a schematic diagram showing the support substrate detachment step S110 of the present embodiment. The support substrate detachment step S110 is a step of detaching the support substrate 40 from the base material 10. In the support substrate detachment step S110 of the present embodiment, the adhesive 30 may be dissolved by a solvent, or a laser may be irradiated through a light-transmitting support substrate 40 to weaken an adhesive force of the adhesive 30. Further, the support substrate detachment step S110 may be a step of detaching the support substrate 40 from the base material 10 by mechanical peeling, in which a sharp tool is inserted between the base material 10 and the support substrate 40 to peel off the adhesive 30.

After the support substrate detachment step S110, the pick-up step S120 (not shown) is performed. The pick-up step S120 is a step of individually removing the singulated semiconductor devices 1 on the dicing tape 50 from the dicing tape 50. Through the above steps, the semiconductor device 1 can be manufactured.

According to the manufacturing method of the present embodiment, since the semiconductor chips 10T are singulated by the step-shaped groove portion 11, the semiconductor device 1 having a step shape on the side surface 10c can be manufactured. Also, as shown in FIG. 15, the inner surface of the first groove 11a becomes the first side surface portion 10d of the semiconductor chip 10T. The bottom portion 11c of the first groove 11a becomes the step surface portion 10f of the semiconductor chip 10T. The inner surface of the second groove 11b becomes the second side surface portion 10e of the semiconductor chip 10T.

Next, effects of the present embodiment will be described. In a method for manufacturing a semiconductor device in the related art, after a metal film is formed, a base material is cut and singulated with a dicing blade. In this case, there is a problem that chipping is likely to occur in the base material at a boundary portion between the metal film and the base material. Thus, in order to inhibit occurrence of chipping of the base material, there is a case of adopting a manufacturing method in which the base material is singulated to form semiconductor chips and then the metal film is formed. In this case, in the metal film forming step, the metal film may be formed to connect the semiconductor chips to each other, and burrs of the metal film may remain. The burrs of the metal film hinder a smooth mounting step, such as hindering the pick-up of the semiconductor chips.

As shown in FIG. 3, the method for manufacturing the semiconductor device 1 of the present embodiment includes the groove portion forming step S20, the first attachment step S30, the grinding step S40, the first ashing step S50, and the metal film forming step S80. The groove portion forming step S20 shown in FIGS. 5 and 6 is a step of forming the plurality of groove portions 11 in the base material 10 from the device surface 10a side in which the element region is formed. The first attachment step S30 shown in FIG. 7 is a step of attaching the device surface 10a to the support substrate 40 via the adhesive 30. The grinding step S40 shown in FIG. 8 is a step of grinding the base material 10 from the side opposite to the device surface 10a to form the back surface 10b. The grinding step S40 is a step of singulating the base material 10 by making the thickness H of the base material 10 equal to or less than the depth D of the groove portions 11. The first ashing step S50 shown in FIG. 9 is a step of performing ashing of the adhesive 30 inside the groove portions 11 from the back surface 10b side. The metal film forming step S80 shown in FIG. 12 is a step of forming the metal film on the back surface 10b.

According to the above-described configuration, the groove portions 11 are formed in the base material 10, the base material 10 is ground from the back surface 10b side to cause the groove portions 11 to penetrate therethrough, and the base material 10 is singulated into the plurality of semiconductor chips 10T. For this reason, as compared to a case in which the base material 10 is cut after it is ground, the groove portions 11 can be formed while the base material 10 is thick, and chipping of the base material 10 in the groove portion forming step S20 can be inhibited. Also, according to the above-described configuration, the metal film 20 is formed after the semiconductor chips 10T are formed. For this reason, occurrence of chipping of the base material 10 at the boundary portion between the metal film 20 and the base material 10 can be inhibited in a singulation step of the base material 10. In addition, according to the above-described configuration, after the adhesive 30 (in-groove adhesive 32) inside the groove portions 11 is ashed from the back surface 10b side, the metal film 20 is formed on the back surface 10b. Thus, the adhesive 30 is ashed on the back surface 10b side of the base material 10t and at the boundary portions between the singulated semiconductor chips 10T, and thus the recessed concave grooves 11A can be formed. For this reason, in the metal film forming step S80, the metal films 20 of the adjacent semiconductor chips 10T sandwiching the concave grooves 11A can be disconnected by the concave grooves 11A. As a result, connection of the metal films 20 formed on the adjacent semiconductor chips 10T can be inhibited, and occurrence of burrs in the metal film 20 can be inhibited. That is, according to the above-described configuration, the semiconductor device 1 with improved quality can be provided. Further, according to the above-described configuration, the side surface 10c of the semiconductor chip 10T can be exposed through the first ashing step S50. Thus, the metal film 20 can also be formed on a part of the side surface 10c of the semiconductor chip 10T in the metal film forming step S80, and the side surface 10c of the semiconductor chip 10T can be protected by the metal film 20. In particular, according to the present embodiment, as shown in FIG. 2, the side surface covering portion 22 connected to the back surface covering portion 21 can be formed. For this reason, peeling of the metal film 20 at the corner portion 10g of the semiconductor chip 10T can be inhibited. Furthermore, according to the present embodiment, by adjusting the depth J of the in-groove adhesive ashed in the first ashing step S50 shown in FIG. 9, a range of the metal film 20 formed on the side surface 10c of the semiconductor chip 10T can be easily adjusted. Thus, only a region of the side surface 10c of the semiconductor chip 10T that needs to be protected can be covered with the metal film 20.

In the method for manufacturing the semiconductor device 1 of the present embodiment, the groove portion forming step S20 is a step of forming the groove portions 11 including the first grooves 11a and the second grooves 11b. In addition, the groove portion forming step S20 includes the first step S21 and the second step S22. The first step S21 shown in FIG. 5 is a step of forming the first grooves 11a on the device surface 10a using the first dicing blade 9a. The second step S22 shown in FIG. 6 is a step of forming the second grooves 11b on the bottom portions 11c of the first grooves 11a using the second dicing blade 9b having a narrower blade width than the first dicing blade 9a. The grinding step S40 shown in FIG. 8 is a step of grinding the base material 10 from the side opposite to the device surface 10a until the thickness H of the base material 10 is greater than the depth d1 of the first grooves 11a and is equal to or less than the depth D of the groove portions 11.

According to above-described configuration, the step shapes can be formed on the inner side surfaces of the groove portions 11. Thus, in the metal film forming step S80 shown in FIG. 12, the metal films 20 of the semiconductor chips 10T adjacent to each other across the concave grooves 11A are likely to be disconnected due to the step portions 11d. As a result, occurrence of burrs on the metal film 20 is likely to be inhibited.

In the method for manufacturing the semiconductor device 1 of the present embodiment, the first ashing step S50 shown in FIG. 9 is a step of removing the adhesive 30 inside the groove portions 11 from the back surface 10b side to positions beyond the bottom portions 11c of the first grooves 11a.

According to the above-described configuration, in the first ashing step S50, the step portions 11d can be exposed on the inner surfaces of the concave grooves 11A. Thus, in the metal film forming step S80, the step portions 11d can function as shields, and occurrence of burrs on the metal film 20 can be more reliably inhibited.

As shown in FIG. 2, the semiconductor device 1 of the present embodiment has the plate-shaped semiconductor chip 10T and the metal film 20. The semiconductor chip 10T is made of a semiconductor material. The metal film 20 is provided on a part of the surface of the semiconductor chip 10T. The semiconductor chip 10T has the device surface 10a, the back surface 10b, and the plurality of side surfaces 10c. The element region is formed on the device surface 10a. The back surface 10b is located on the side opposite to the device surface 10a. The plurality of side surfaces 10c connect the device surface 10a to the back surface 10b. The side surface 10c has the first side surface portion 10d, the second side surface portion 10e, and the step surface portion 10f, which are disposed in a stepped shape. The first side surface portion 10d and the second side surface portion 10e extend along a plane perpendicular to the device surface 10a. The second side surface portion 10e is located closer to the back surface 10b than the first side surface portion 10d in the normal direction of the device surface 10a. The second side surface portion 10e is located farther from the center of gravity G of the semiconductor chip 10T than the first side surface portion 10d in the normal direction of the first side surface portion 10d. The step surface portion 10f connects the first side surface portion 10d to the second side surface portion 10e. The metal film 20 has the back surface covering portion 21 and the side surface covering portion 22. The back surface covering portion 21 covers the back surface. The side surface covering portion 22 covers at least a part of the side surface 10c.

According to the above-described configuration, the metal film 20 can be used as an electrode of the semiconductor device 1. In addition, since the metal film 20 has not only the back surface covering portion 21 but also the side surface covering portion 22, the side surface of the semiconductor chip 10T can be protected. Thus, occurrence of chipping of the side surface 10c of the semiconductor device 1 can be inhibited when the semiconductor device 1 is transported and mounted on a lead frame in the pick-up step S120.

In the semiconductor device 1 of the present embodiment, the side surface covering portion 22 covers the second side surface portion 10e. According to the present embodiment, the second side surface portion 10e is provided on the side surface 10c to protrude outward from the semiconductor chip 10T. For this reason, by protecting the second side surface portion 10e with the metal film 20, occurrence of chipping of the side surface 10c of the semiconductor device 1 can be effectively inhibited.

In the semiconductor device 1 of the present embodiment, the back surface covering portion 21 and the side surface covering portion 22 are connected to each other.

According to the above-described configuration, a wide bonding area between the metal film 20 and the semiconductor chip 10T can be secured, and peeling of the metal film 20 from the semiconductor chip 10T can be inhibited. Further, the metal film 20 of the present embodiment covers the corner portion 10g between the back surface 10b and the side surface 10c of the semiconductor chip 10T. Thus, peeling of the metal film 20 from the corner portion 10g of the semiconductor chip 10T can be inhibited. Furthermore, when the metal film 20 has a plurality of layers, the back surface covering portion 21 and the side surface covering portion 22 are connected to each other, and thus the layer structure can be bent. Thus, delamination of the metal film 20 due to differences in thermal expansion coefficient between the layers constituting the metal film 20 is likely to be inhibited.

### Second Embodiment

A semiconductor device 101 of a second embodiment and a manufacturing method thereof will be described. In the following description, the same configurational aspects as those in the above-described embodiment will be denoted by the same reference signs, and descriptions thereof will be omitted.

FIG. 16 is a schematic cross-sectional view of the semiconductor device 101 of the second embodiment. As in the above-described embodiment, the semiconductor device 101 of the present embodiment includes a semiconductor chip 110T and a metal film 120. The semiconductor chip 110T has a device surface (first surface) 110a, a back surface (second surface) 110b, and four side surfaces 110c.

The side surface 110c of the semiconductor chip 110T has a flat surface portion 110d extending in a direction perpendicular to the device surface 110a, and an inclined portion 110e inclined with respect to the flat surface portion 110d.

The flat surface portion 110d is connected to the device surface 110a. The inclined portion 110e is located closer to the back surface 110b than the flat surface portion 110d. The inclined portion 110e is connected to both the flat surface portion 110d and the back surface 110b. The inclined portion 110e is inclined in a direction away from a center of gravity G of the semiconductor chip 110T toward the back surface 110b from the device surface 110a.

The metal film 120 of the present embodiment has a back surface covering portion (second surface covering portion) 121 and a side surface covering portion 122. The back surface covering portion 121 covers the entire back surface 110b of the semiconductor chip 110T.

The side surface covering portion 122 covers at least a part of the side surface 110c of the semiconductor chip 110T. The side surface covering portion 122 is provided in a certain region from corner groove portions 110g between the side surface 110c and the back surface 110b toward the device surface 110a. The side surface covering portion 122 of the present embodiment covers a part of the inclined portion 110e of the side surface 110c and does not cover the flat surface portion 110d. According to the present embodiment, the metal film 120 covers at least a part of the side surface 110c, and thus the metal film 120 can protect the part of the side surface 110c.

Similarly to the method for manufacturing the semiconductor device 1 of the first embodiment (see FIG. 3), a method for manufacturing the semiconductor device 101 of the present embodiment has the device surface forming step S10, the groove portion forming step S20, the first attachment step S30, the grinding step S40, the first ashing step S50, the metal film forming step S80, the second ashing step S90, the second attachment step S100, the support substrate detachment step S110, and the pick-up step S120. In the manufacturing method of the present embodiment, the protective film forming step S60 and the etching step S70 described in the first embodiment are omitted. Characteristic steps in the method for manufacturing the semiconductor device 101 of the present embodiment will be described below.

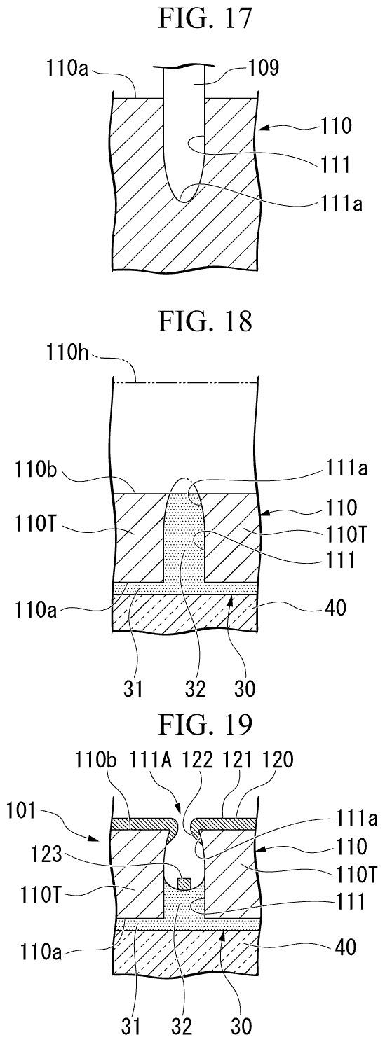

FIG. 17 is a schematic diagram showing the groove portion forming step S20 of the present embodiment. The groove portion forming step S20 of the present embodiment is performed using a dicing blade 109 whose blade width narrows toward its tip. In the groove portion forming step S20, a base material 110 is processed using the dicing blade 109 to form a groove portion 111 on the device surface 110a. The groove portion 111 has a narrowed portion 111a whose groove width narrows toward its bottom portion.

Also, in the groove portion forming step S20 of the present embodiment, the groove portion 111 having the narrowed portion 111a is formed using the dicing blade 109. However, the groove portion forming step S20 may adopt laser dicing or dicing by etching. Even when these methods are adopted to form the groove portion, a narrowed portion can be formed in the groove portion as in the present embodiment.

FIG. 18 is a schematic diagram showing the grinding step S40 of the present embodiment. The base material 110 is turned upside down between the groove portion forming step S20 and the grinding step S40. The grinding step S40 is a step of grinding an initial back surface 110h of the base material 110 to form the back surface (second surface) 110b. The grinding step S40 of the present embodiment is performed while the base material 110 is supported by the support substrate 40. Accordingly, as in the first embodiment, the grinding step S40 is performed while the groove portion 111 of the base material 110 is filled with the adhesive 30.

Through the grinding step S40, the base material 110 is ground to a thickness smaller than a depth of the groove portion 111. Thus, the groove portion 111 penetrates the base material 110, and the base material 110 is singulated to form a plurality of semiconductor chips 110T. In particular, in the grinding step S40 of the present embodiment, the base material 110 is ground to a middle of the narrowed portion 111a of the groove portion 111. Accordingly, in the grinding step S40, the narrowed portion 111a is not completely removed. Thus, the narrowed portion 111a is disposed at an opening portion of the groove portion 111 on the back surface 110b side.

FIG. 19 is a schematic diagram showing the base material 110 after the first ashing step S50 and the metal film forming step S80 of the present embodiment have been performed. The first ashing step S50 is a step of removing the in-groove adhesive 32 from the back surface 110b side to the narrowed portion 111a or to a position beyond the narrowed portion 111a. Through the first ashing step S50, a concave groove 111A formed by ashing of the adhesive 30 is formed on the back surface 110b side of the base material 110 and at boundary portions between the singulated semiconductor chips 110T.

The groove width of the concave groove 111A gradually increases from an opening of the back surface 110b toward the device surface 110a.

The metal film forming step S80 is a step of forming the metal film 120 on the back surface 110b of the base material 110. The metal film 120 is formed not only on the back surface 110b, but also on the side surface of the semiconductor chip 110T and on the in-groove adhesive 32. That is, the metal film 120 includes the back surface covering portion 121 formed on the back surface 110b, the side surface covering portion 122 formed on the side surface of the semiconductor chip 110T, and an adhesive covering portion 123 formed on the in-groove adhesive 32. An opening portion of the concave groove 111A functions as a shield, and thus the adhesive covering portion 123 is formed only at a center of the in-groove adhesive 32 in a width direction.

Next, effects of the present embodiment will be described. In the present embodiment, the groove portion forming step S20 is a step of forming the groove portions 111. In the groove portion forming step S20, the narrowed portion 111a whose groove width is narrowed toward its bottom portion is provided. The grinding step S40 is a step of grinding the base material 110 from a side opposite to the device surface 110a to the middle of the narrowed portion 111a.

According to the above-described configuration, a shield shape can be formed by the narrowed portion 111a on the inner side surface of the groove portion 111. Thus, the metal films 120 of the semiconductor chips 110T adjacent to each other across the concave groove portions 111A in the metal film forming step S80 can be more reliably disconnected. In addition, according to this configuration, the semiconductor chips 110T can be singulated without dicing the metal film 120. As a result, occurrence of burrs on the metal film 120 formed on the semiconductor chips 110T adjacent to each other can be reliably inhibited. Also, the groove portion forming step S20 of the present embodiment is performed using the dicing blade 109 whose blade width is narrowed toward its tip. Thus, the groove portion 111 having the narrowed portion 111a can be easily formed.

In the present embodiment, the first ashing step S50 is a step of removing the adhesive 30 inside the groove portion 111 from the back surface 110b side to the middle of the narrowed portion 111a or to a position beyond the narrowed portion 111a.

According to the above-described configuration, the narrowed portion 111a of the groove portion 111 can be exposed from the adhesive 30 in the first ashing step S50. Thus, in the metal film forming step S80, the narrowed portion 111a can function as a shield, and occurrence of burrs on the metal film 120 can be more reliably inhibited.

As shown in FIG. 16, the semiconductor device 101 of the present embodiment has the plate-shaped semiconductor chip 110T and the metal film 120. The semiconductor chip 110T is made of a semiconductor material. The metal film 120 is provided on a part of the surface of the semiconductor chip 110T. The semiconductor chip 110T has the device surface 110a, the back surface 110b, and the plurality of side surfaces 110c. The element region is formed on the device surface 110a. The back surface 110b is located on the side opposite to the device surface 110a. The plurality of side surfaces 110c connect the device surface 110a to the back surface 110b. The side surface 110c has the inclined portion 110e that is inclined in a direction away from the center of gravity G of the semiconductor chip 110T toward the back surface 110b from the device surface 110a. The metal film 120 has the back surface covering portion 121 and the side surface covering portion 122. The back surface covering portion 121 covers the back surface. The side surface covering portion 122 covers at least a part of the side surface 110c.

According to the above-described configuration, the metal film 120 can be used as an electrode of the semiconductor device 101. In addition, since the metal film 120 has not only the back surface covering portion 121 but also the side surface covering portion 122, the side surface of the semiconductor chip 110T can be protected. Thus, occurrence of chipping of the side surface 110c of the semiconductor device 101 when the semiconductor device 101 is transported and mounted on a lead frame in the pick-up step S120, or the like can be inhibited. Further, in the semiconductor device 101 of the present embodiment, the back surface covering portion 121 and the side surface covering portion 122 are connected to each other. For this reason, a wide bonding area between the metal film 120 and the semiconductor chip 110T can be secured, and peeling of the metal film 120 can be inhibited. Furthermore, since the metal film 120 covers the corner groove portion 110g of the semiconductor chip 110T, peeling of the metal film 120 from the corner groove portion 110g is likely to be inhibited.

### Modified Examples of the Second Embodiment

A method for manufacturing a semiconductor device 201 of a modified example of the second embodiment will be described. Also, in the following description, the same configurational aspects as in the above-described embodiment will be denoted by the same reference signs, and descriptions thereof will be omitted.

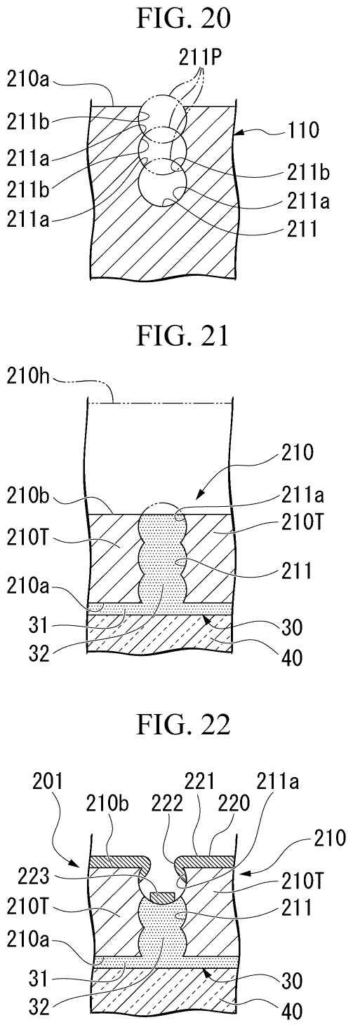

FIG. 20 is a schematic diagram of a base material 210 after the groove portion forming step S20 of the present modified example has been performed. The groove portion forming step S20 of the present modified example is a step of forming a groove portion 211 by plasma dicing. In the plasma dicing, a device surface 210a of the base material 210 is masked except for the portion in which the groove portion 211 is to be formed, the groove portion 211 is formed by plasma processing, and then the mask is removed.

In the groove portion forming step S20 of the present modified example, a case in which plasma dicing is performed three times is exemplified. In the plasma dicing, element grooves 211P having a circular cross-section are formed on a surface of the base material 210 each time the plasma processing is performed. In the groove portion forming step S20 shown in FIG. 20, by performing plasma dicing three times, the element grooves 211P are formed in a line in a depth direction thereof, and the groove portions 211 of sufficient depth are formed.

The groove portion 211 formed in the groove portion forming step S20 of the present modified example has a cross-sectional shape in which portions having widened groove widths and portions having narrowed groove widths are alternately arranged in the depth direction. That is, the groove portion 211 of the present modified example has a first narrowed portion 211a and a second narrowed portions 211b, which are alternately arranged in a thickness direction of the base material 210. The groove width of the first narrowed portion 211a is narrowed in a direction away from the device surface 210a. The groove width of the second narrowed portion 211b is narrowed in a direction coming closer to the device surface 210a.

FIG. 21 is a schematic diagram showing the grinding step S40 of the present modified example. The base material 210 is turned upside down between the groove portion forming step S20 and the grinding step S40. The grinding step S40 is a step of grinding an initial back surface 210h of the base material 210 to form a back surface (second surface) 210b. The grinding step S40 of the present modified example is performed while the base material 210 is supported on the support substrate 40. Accordingly, similarly to the first modified example, the grinding step S40 is performed while the groove portions 211 of the base material 210 are filled with the adhesive 30.

Through the grinding step S40, the base material 210 is ground to a thickness smaller than the depth of the groove portions 211. Thus, the groove portions 211 penetrate the base material 210, the base material 210 is singulated, and a plurality of semiconductor chips 210T are formed. In particular, in the grinding step S40 of the present modified example, the base material 210 is ground to a middle of one first narrowed portion 211a. In the grinding step S40 shown in FIG. 21, grinding is performed up to one of a plurality of first narrowed portions 211a that is the farthest from the device surface 210a. Thus, the first narrowed portion 211a is disposed at an opening portion of the groove portion 211 on the back surface 210b side. Also, in the grinding step S40, grinding may be performed further up to other first narrowed portions 211a. That is, the first narrowed portion 211a disposed at the opening portion in the grinding step S40 may be any one of the plurality of first narrowed portions 211a.

FIG. 22 is a schematic diagram showing the base material 210 after the first ashing step S50 and the metal film forming step S80 of the present modified example have been performed. The first ashing step S50 is a step of removing the in-groove adhesive 32 from the back surface 210b side to the first narrowed portion 211a or to a position beyond the first narrowed portion 211a. Since the groove portion 211 has the first narrowed portion 211a, a width of the groove portion 211 increases from the back surface 210b toward the device surface 210a.

The metal film forming step S80 is a step of forming a metal film 220 on the back surface 210b of the base material 210. Similarly to the second embodiment, the metal film 220 includes a back surface covering portion 221 formed on the back surface 210b, a side surface covering portion 222 formed on an inner surface of the groove portion 211, and an adhesive covering portion 223 formed on the in-groove adhesive 32. Since the first narrowed portion 211a functions as a shield, the adhesive covering portion 223 is formed only at the center of the in-groove adhesive 32 in the width direction.

According to the present modified example, similarly to the second embodiment, the metal films 220 of the semiconductor chips 210T can be more reliably disconnected from each other. As a result, occurrence of burrs on the metal films 220 formed on the semiconductor chips 210T adjacent to each other can be more reliably inhibited. According to the present modified example, other effects similar to those of the second embodiment can be obtained.

According to the present modified example, since the groove portion 211 is formed by plasma dicing in the groove portion forming step S20, a planar shape of the groove portion 211 can be freely designed depending on a shape of the mask used when the plasma dicing is performed. Thus, a semiconductor chip 210T with an optimized shape in a plan view, such as a semiconductor chip 210T having a hexagonal shape in a plan view, can be formed.

According to at least one of the manufacturing methods of the embodiments described above, by including the first ashing step S50 in which ashing of the adhesive 30 is performed and the metal film forming step S80 performed after the first ashing step S50, the metal film can be disconnected by the concave grooves formed by ashing, and the semiconductor devices 1, 101, and 201 with fewer burrs can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device comprising:
a groove portion forming step of forming a plurality of groove portions in a base material from a first surface side on which an element region is formed;
an attachment step of attaching the first surface to a support substrate via an adhesive;
a grinding step of grinding the base material from a side opposite to the first surface to form a second surface and singulating the base material by making a thickness of the base material equal to or less than depths of the groove portions;
an ashing step of ashing the adhesive inside the groove portions from the second surface side; and
a film forming step of forming a metal film on the second surface.

2. The method for manufacturing a semiconductor device according to claim 1,
wherein the groove portion forming step is a step of forming the groove portions including first grooves and second grooves,
the groove portion forming step includes a first step of forming the first grooves on the first surface using a first dicing blade, and a second step of forming the second grooves at bottom portions of the first grooves using a second dicing blade having a narrower blade width than the first dicing blade, and
the grinding step is a step of grinding the base material from the side opposite to the first surface until the thickness of the base material becomes greater than the depths of the first grooves and equal to or less than the depths of the groove portions.

3. The method for manufacturing a semiconductor device according to claim 2,
wherein the ashing step is a step of removing the adhesive inside the groove portions from the second surface side to a position beyond the bottom portions.

4. The method for manufacturing a semiconductor device according to claim 1,
wherein the groove portion forming step is a step of forming the groove portions each having a narrowed portion whose groove width narrows toward a bottom portion thereof, and
the grinding step is a step of grinding the base material from the side opposite to the first surface to a middle of the narrowed portion.

5. The method for manufacturing a semiconductor device according to claim 4,
wherein the ashing step is a step of removing the adhesive inside the groove portions from the second surface side to the middle of the narrowed portion or to a position beyond the narrowed portion.

6. The method for manufacturing a semiconductor device according to claim 1,
wherein the grinding step is a step of exposing the adhesive inside the groove portions from the second surface side.

7. A semiconductor device comprising:
a plate-shaped semiconductor chip made of a semiconductor material; and
a metal film provided on a part of a surface of the semiconductor chip,
wherein the semiconductor chip includes a first surface on which an element region is formed, a second surface located on a side opposite to the first surface, and a plurality of side surfaces that connect the first surface to the second surface,
each of the side surfaces has a first side surface portion, a second side surface portion, and a step surface portion, which are disposed in a stepped shape,
the first side surface portion and the second side surface portion extend along a plane perpendicular to the first surface,
the second side surface portion is located on a side closer to the second surface than the first side surface portion in a normal direction to the first surface and on a side farther from a center of gravity of the semiconductor chip than the first side surface portion in a normal direction to the first side surface portion,
the step surface portion connects the first side surface portion to the second side surface portion, and
the metal film includes a second surface covering portion covering the second surface, and a side surface covering portion covering at least a part of the side surfaces.

8. The semiconductor device according to claim 7,
wherein the side surface covering portion covers the second side surface portion.

9. A semiconductor device comprising:
a plate-shaped semiconductor chip made of a semiconductor material; and
a metal film provided on a part of a surface of the semiconductor chip,
wherein the semiconductor chip includes a first surface on which an element region is formed, a second surface located on a side opposite to the first surface, and a plurality of side surfaces that connect the first surface to the second surface,
each of the side surfaces has an inclined portion that is inclined in a direction away from a center of gravity of the semiconductor chip toward the second surface from the first surface, and
the metal film includes a second surface covering portion covering the second surface, and a side surface covering portion covering at least a part of the side surfaces.

10. The semiconductor device of claim 7,
wherein the second surface covering portion and the side surface covering portion are connected to each other.
